(19) United States
(12) Patent Application Publication
(10) Pub. No.: US 2024/0011608 A1
(43) Pub. Date: Jan. 11, 2024

(54) LAMP BEAD CAPABLE OF EMITTING LIGHT BY 360 DEGREES

(71) Applicant: Zhejian Qu, Taizhou (CN)

(72) Inventor: Zhejian Qu, Taizhou (CN)

(73) Assignee: Taizhou Richangjing Lighting Co., Ltd., Taizhou (CN)

(21) Appl. No.: 18/471,284

(22) Filed: Sep. 20, 2023

(30) Foreign Application Priority Data
Sep. 30, 2022 (CN) 202211217090.0

(51) Int. Cl. F21S 4/20

(52) U.S. Cl. CPC F21S 4/20; F21Y 2103/10

(57) ABSTRACT

The present invention discloses a lamp bead capable of emitting light by 360 degrees. The technical solution of the present invention includes a conductive sheet, a light-emitting chip and an encapsulation colloid, wherein both ends of the conductive sheet are respectively connected to two external electrode wires; the conductive sheet has a hollow cavity in the middle; the light-emitting chip is installed on the conductive sheet; both ends of the light-emitting chip are connected to the conductive sheet; and the encapsulation colloid is coated to the front and back sides of the conductive sheet to wrap and fix the light-emitting chip. The light-emitting chip is wrapped by the encapsulating colloid at one time to achieve encapsulation. A light source on the light-emitting chip can transmit the hollow cavity, so that light can be transmitted to the back side.

### TECHNICAL FIELD

The present invention relates to the technical field of LEDs, in particular to a lamp bead capable of emitting light by 360 degrees.

### BACKGROUND OF THE INVENTION

At present, the conventional light-emitting chip is fixed on a PVC board, and thus can emit light from the front side, rather than the back side blocked by the PVC board. After improvement, light-emitting chips are installed on both sides of the PVC board, so the production cost increases although the comprehensive light-emitting problem is solved.

In addition, for example, the patent, having an authorization announcement No: CN207504009, discloses a two-color electrodeless lamp bead. The technical solution of the two-color electrodeless lamp bead includes a substrate on which a first bowl cup and a second bowl cup are disposed, wherein a first LED chip and a second LED chip are disposed in the first bowl cup and the second bowl cup, respectively; the first bowl cup is filled with a first encapsulation colloid, and the second bowl cup is filled with a second encapsulation colloid; a first weld leg and a second weld leg are respectively disposed on both sides of the substrate respectively; and an anode of the first LED chip and a cathode of the second LED chip are respectively connected to the first weld leg, and a cathode of the first LED chip and an anode of the second LED chip are respectively connected to the second weld leg. This structure makes the entire lamp bead almost completely transparent and has 360-degree luminescence. However, this encapsulation method requires the use of a transparent bracket or housing, wherein it is necessary to fix a conductive sheet to the bracket first, and then install the chip and wrap the colloid, so secondary packaging is required. The traditional TOP encapsulation method is adopted, which increases the encapsulation cost and production cost.

### SUMMARY OF THE INVENTION

In view of the shortcomings of the prior art, the present invention provides a lamp bead capable of emitting light by 360 degrees, which has a simple structure and low production cost, and can achieve full-angle luminescence.

To fulfill said object, the present invention adopts the following technical solutions. A lamp bead capable of emitting light by 360 degrees includes:
a conductive sheet, both ends of the conductive sheet being respectively connected to two external electrode wires, the conductive sheet having a hollow cavity in the middle;
a light-emitting chip, the light-emitting chip being installed on the conductive sheet, both ends of the light-emitting chip being connected to the conductive sheet; and
an encapsulation colloid, the encapsulation colloid being coated to the front side and the back side of the conductive sheet to wrap and fix the light-emitting chip.

Preferably, the light-emitting chip is lapped above the hollow cavity, both sides of the light-emitting chip are installed on the conductive sheet, a light source on the light-emitting chip corresponds to the hollow cavity, and the light source can pass through the hollow cavity, so that light can also be transmitted to the back side to achieve 360-degree luminescence.

Preferably, the light-emitting chip is installed on the left or right side of the conductive sheet; and after the light-emitting chip is wrapped by the encapsulation colloid even being on one side, the light can still be refracted to transmit the hollow cavity, thereby achieving 360-degree luminescence.

Preferably, the light-emitting chip is installed in the hollow cavity of the conductive sheet, which can reduce an installation area and a protruding area of the light-emitting chip; and the light-emitting chip is firmly fixed while 360-degree luminescence can also be realized.

Preferably, a diode chip is adopted as the light-emitting chip.

Preferably, the conductive sheet has a thickness of 0.05 mm to 0.3 mm.

Preferably, the conductive sheet may be made of an iron sheet or copper sheet, which can be selected according to actual demands.

Preferably, the encapsulation colloid is made of transparent epoxy resin, which can protect an internal structure of the chip, and can slightly change a light-emitting color, brightness and angle to make the light shaped.

Preferably, the encapsulation colloid is made of a mixture of fluorescent powder and transparent epoxy resin. The mixed fluorescent powder can be made into different colors, and the light color will become softer.

Preferably, the fluorescent powder includes but is not limited to one or a mixture of more of white, yellow, red, blue or green, and the color can be selected according to actual needs.

Preferably, the encapsulation colloid is smoothly coated onto the front and back sides of the conductive sheet; and both ends of the conductive sheet are not coated with the encapsulation colloid, but used for being connected to external electrode wires.

The present invention has the following beneficial effects:
the light-emitting chip is installed on the conductive sheet, and the anode and cathode on both ends of the light-emitting chip are connected to the external electrode wires; and the light-emitting chip is wrapped by the encapsulating colloid at one time to achieve encapsulation. The light source on the light-emitting chip can pass through the hollow cavity, so that light can be transmitted to the back side. The light-emitting chip can be encapsulated by a QFP encapsulation method instead of the traditional top encapsulation method. The lamp bead of the present invention has a simple structure and low production cost, and can achieve 360-degree full-angle luminescence.

### BRIEF DESCRIPTION OF DRAWINGS

FIG. 1 is a schematic diagram in which a light-emitting chip is installed on a conductive sheet in Embodiment 1 of the present invention;

FIG. 2 is a schematic structural diagram of the front side after wrappage with an encapsulation colloid in Embodiment 1 of the present invention;

FIG. 3 is a schematic diagram of the connection of the conductive sheet and two electrode wires after wrappage with the encapsulation colloid in Embodiment 1 of the present invention;

FIG. 4 is a schematic diagram of the installation of an overall internal structure in Embodiment 1 of the present invention;

FIG. 5 is a schematic diagram of the installation of an overall internal structure in Embodiment 2 of the present invention; and

FIG. 6 is a schematic diagram of the installation of an overall internal structure in Embodiment 5 of the present invention.

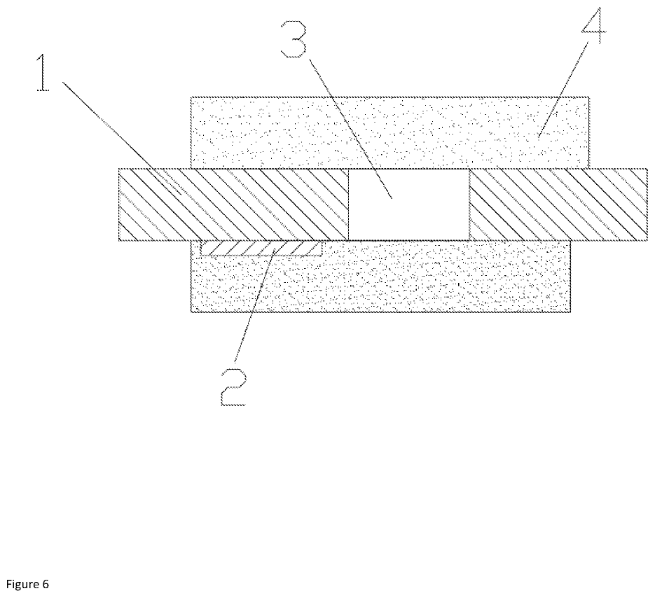

Reference symbols represent the following components: 1—conductive sheet; 2—light-emitting chip; 3—hollow cavity; 4—encapsulation colloid; 5—electrode wire.

### DETAILED DESCRIPTION OF THE INVENTION

In order to facilitate the understanding of the present invention, the present invention will be described more comprehensively with reference to the relevant drawings below. Preferred embodiments of the present invention are given in the drawings. However, the present invention may be implemented in many different forms and is not limited to the embodiments described herein. On the contrary, the purpose of providing these embodiments is to make the disclosure of the present invention more thorough and comprehensive.

It should be noted that when an element is referred to as being “fixed to” another element, it may be directly located on the other element, or an intermediate element may also exist. When an element is referred to as being “connected to” another element, it may be directly connected to the other element, or an intermediate element exists at the same time. The terms “vertical”, “horizontal”, “left”, “right” and similar expressions used in the present invention are for the purpose of illustration.

Unless otherwise defined, all technical and scientific terms used in the present invention have the same meaning as commonly understood by a person of ordinary skill in the art. The terms used in the description of the present invention herein are only for the purpose of describing specific embodiments, and are not intended to limit the present invention. The term “and/or” as used herein includes any and all combinations of one or more related listed items.

### Embodiment 1

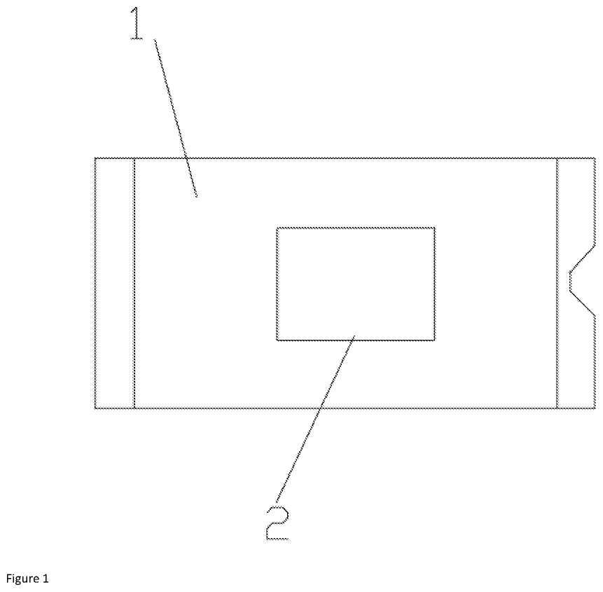

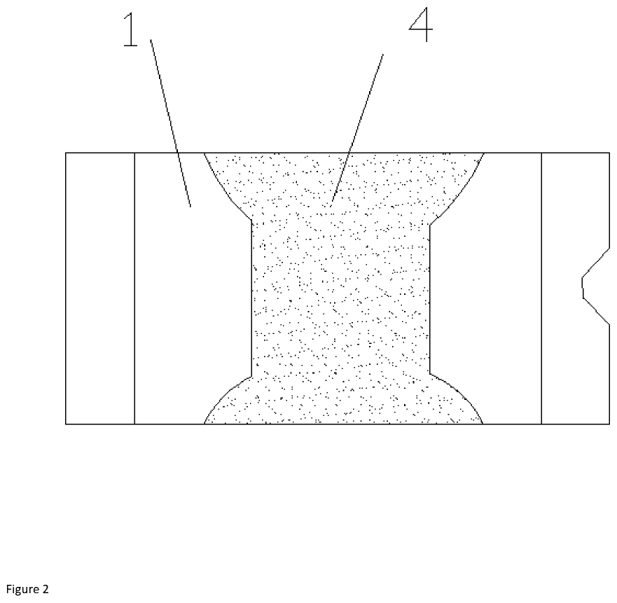

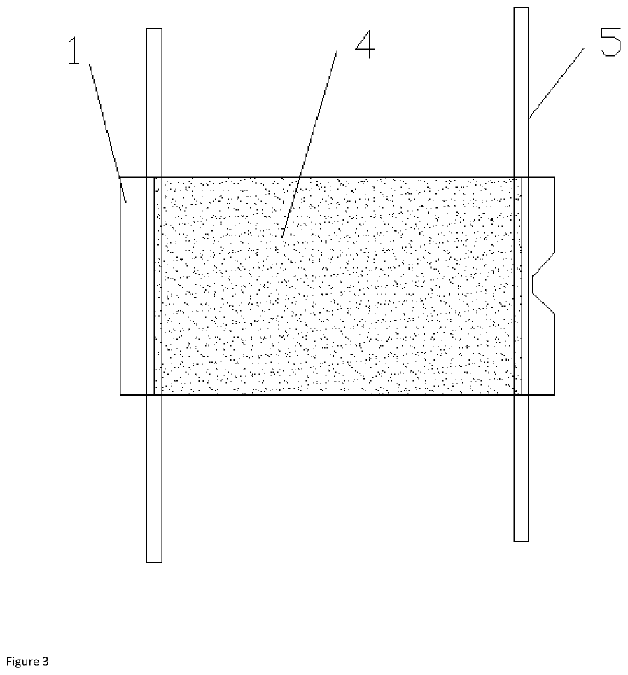

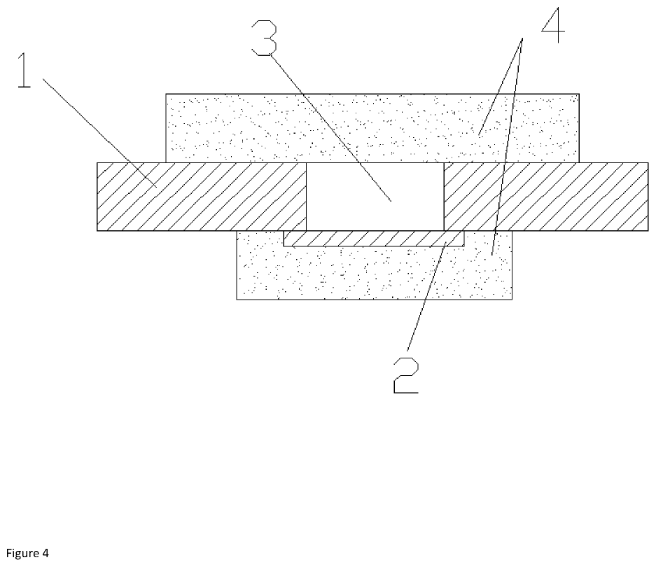

Referring to FIGS. 1 to 4, a lamp bead capable of emitting light by 360 degrees includes a conductive sheet 1, a light-emitting chip 2 and an encapsulation colloid 4, wherein both ends of the conductive sheet 1 are respectively connected to two external electrode wires 5; the conductive sheet 1 has a hollow cavity 3 in the middle, and the size of the cavity is determined according to a size of the light-emitting chip 2; the light-emitting chip 2 is installed in the middle of the conductive sheet 1; both ends of the light-emitting chip 2 are connected to the conductive sheet 1; the encapsulation colloid 4 is smoothly coated to the front and back sides of the conductive sheet 1 to wrap and fix the light-emitting chip 2; and both ends of the conductive sheet 1 are not coated with the encapsulation colloid and used for being connected to the external electrode wires 5 by means of welding.

The light-emitting chip 2 is lapped above the hollow cavity 3, and both sides of the light-emitting chip 2 are installed on the conductive sheet 1. A diode chip is adopted as the light-emitting chip 2. The diode chip is a conventional chip, which is not specifically described in this embodiment. Both ends of the diode chip may be directly connected to the conductive sheet 1. A light source on the light-emitting chip 2 can transmit the hollow cavity 3, so that light can be transmitted to the back side.

The conductive sheet 1 may be made of an iron sheet or copper sheet, and other materials can also be selected according to actual needs.

The encapsulation colloid 4 is made of a mixture of fluorescent powder and transparent epoxy resin. The encapsulation colloid can protect an internal structure of the chip, and can slightly change a light-emitting color, brightness and angle to make the light shaped. The mixed fluorescent powder can be made into different colors, and the light color will become softer.

The light-emitting chip 2 is installed in the middle of the conductive sheet 1, and an anode and cathode on both ends of the light-emitting chip 2 are connected to the external electrode wires 5; and the light-emitting chip 2 is wrapped by the encapsulating colloid 4 at one time to achieve encapsulation. The light source on the light-emitting chip 2 can transmit the hollow cavity 3, so that light can be transmitted to the back side. The light-emitting chip 2 can be encapsulated by a QFP encapsulation method instead of the traditional top encapsulation method. The lamp bead of the present invention has a simple structure and low production cost, and can achieve 360-degree full-angle luminescence.

### Embodiment 2

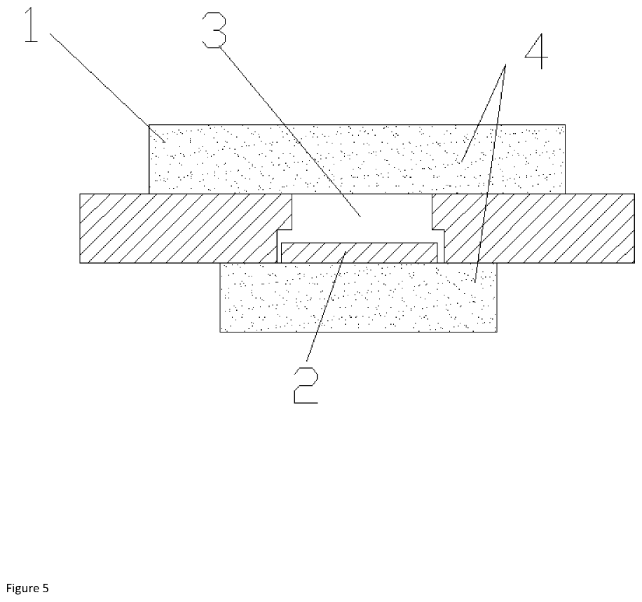

Referring to FIG. 5, a lamp bead capable of emitting light by 360 degrees includes a conductive sheet 1, a light-emitting chip 2 and an encapsulation colloid 4, wherein both ends of the conductive sheet 1 are respectively connected to two external electrode wires 5; the conductive sheet 1 has a hollow cavity 3 in the middle; the light-emitting chip 2 is installed in the hollow cavity 3 of the conductive sheet 1; both ends of the light-emitting chip 2 are connected to the conductive sheet 1 through electric wires; and the encapsulation colloid 4 is coated to the front and back sides of the conductive sheet 1 to wrap and fix the light-emitting chip 2.

Since the light-emitting chip 2 is located in the hollow cavity 3, the installation area and the protruding area of the light-emitting chip 2 can be reduced. The light-emitting chip 2 is firmly fixed. The size and thickness of the conductive sheet 1 are designed according to the size of the light-emitting chip 2, wherein the thickness is controlled between 0.05 mm and 0.3 mm, and may be 0.2 mm in this embodiment. Even the light-emitting chip is embedded in the hollow cavity 3, 360-degree luminescence can be achieved without affecting the light transmission.

### Embodiment 3

This embodiment is basically the same as Embodiment 1, the difference residing in that the encapsulation colloid 4 is made of transparent epoxy resin, which can protect an internal structure of the chip, and can slightly change a light-emitting color, brightness and angle to make the light shaped. Meanwhile, the cured transparent epoxy resin has high bonding strength, and better hardness; and the cured product has good acid and alkali resistance, good moisture-proof, waterproof, oil-proof and dust-proof properties, and resistance to humidity, heat and atmospheric aging; and has good physical properties such as insulation, compression resistance and high bonding strength.

### Embodiment 4

The encapsulation fluid 4 is made of a mixture of fluorescent powder and transparent epoxy resin. The fluorescent powder includes but is not limited to one or a mixture of more of white, yellow, red, blue or green, and the color can be selected according to actual needs.

### Embodiment 5

A lamp bead capable of emitting light by 360 degrees includes a conductive sheet 1, a light-emitting chip 2 and an encapsulation colloid 4, wherein the encapsulation fluid 4 is made of a mixture of fluorescent powder and transparent epoxy resin; both ends of the conductive sheet 1 are respectively connected to two external electrode wires 5; the light-emitting chip 2 is installed on the left or right side of the conductive sheet 1; both ends of the light-emitting chip 2 are connected to the conductive sheet 1 through electric wires; and the encapsulation colloid 4 is coated to the front and back sides of the conductive sheet 1 to wrap and fix the outer surfaces of the light-emitting chip 2 and the hollow cavity 3. After the wrappage with the encapsulation colloid, due to the thin thickness of the conductive sheet 1 and a short distance between the light-emitting chip 2 and the hollow cavity, light can still transmit the hollow cavity 3 after being refracted by the fluorescent powder and the transparent epoxy resin, thereby realizing 360-degree luminescence.

The above-mentioned embodiments only express several implementations of the present invention, and the description is relatively specific and detailed, but it should not be understood as a limitation to the patent scope of the present invention. It should be pointed out that for those of ordinary skill in the art, without departing from the concept of the present invention, several modifications and improvements can be made, and these all fall within the protection scope of the present invention. Therefore, the protection scope of the patent of the present invention should be subject to the appended claims.

1. A lamp bead capable of emitting light by 360 degrees, comprising:
a conductive sheet, both ends of the conductive sheet being respectively connected to two external electrode wires, the conductive sheet having a hollow cavity in the middle;
a light-emitting chip, the light-emitting chip being installed on the conductive sheet, both ends of the light-emitting chip being connected to the conductive sheet; and
an encapsulation colloid, the encapsulation colloid being coated to the front side and the back side of the conductive sheet to wrap and fix the light-emitting chip.

2. The lamp bead capable of emitting light by 360 degrees according to claim 1, wherein the light-emitting chip is installed in the middle of the conductive sheet, and lapped above the hollow cavity.

3. The lamp bead capable of emitting light by 360 degrees according to claim 1, wherein the light-emitting chip is installed on the left or right side of the conductive sheet.

4. The lamp bead capable of emitting light by 360 degrees according to claim 1, wherein the light-emitting chip is installed in the hollow cavity of the conductive sheet.

5. The lamp bead capable of emitting light by 360 degrees according to claim 1, wherein a diode chip is adopted as the light-emitting chip.

6. The lamp bead capable of emitting light by 360 degrees according to claim 1, wherein the light-emitting chip is made of an iron sheet or copper sheet.

7. The lamp bead capable of emitting light by 360 degrees according to claim 1, wherein the encapsulation colloid is made of transparent epoxy resin.

8. The lamp bead capable of emitting light by 360 degrees according to claim 1, wherein the encapsulation colloid is made of a mixture of fluorescent powder and transparent epoxy resin.

9. The lamp bead capable of emitting light by 360 degrees according to claim 8, wherein the fluorescent powder includes but is not limited to one or a mixture of more of white, yellow, red, blue or green.

10. The lamp bead capable of emitting light by 360 degrees according to claim 1, wherein the encapsulation colloid is smoothly coated onto the front and back sides of the conductive sheet; and both ends of the conductive sheet are not coated with the encapsulation colloid, but are used for being connected to external electrode wires.
